(19) United States
(12) Patent Application Publication
(10) Pub. No.: US 2008/0079138 A1
(43) Pub. Date: Apr. 3, 2008

(54) Semiconductor device

(75) Inventor: Norio Takahashi, Miyazaki (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/898,967

(22) Filed: Sep. 18, 2007

(30) Foreign Application Priority Data
Sep. 29, 2006 (JP) 2006-266866

(51) Int. Cl. H01L 23/48

(52) U.S. Cl. 257/698; 257/E23.01

(57) ABSTRACT

A semiconductor device that mounts a semiconductor chip in a multilayer substrate, including, inner layer conductive patterns formed in the multilayer substrate; extending conductive portions formed to extend on inner layer conductive patterns in the thickness direction, in the chip mounting area into which the semiconductor chip is mounted; and a cutout portion that is formed by cutting the multilayer substrate, and into which the semiconductor chip is contained, in the chip mounting area. And, in the cutout portion, the underside surface of the semiconductor chip and the inner layer conductive patterns are connected via the extending conductive portions at a same potential.

### CROSS REFERENCE TO RELATED APPLICATION

This application claims the priority of Application No. 2006-266866, filed Sep. 29, 2006 in Japan, the subject matter of which is incorporated herein by reference.

### TECHNICAL FIELD OF THE INVENTION

The present invention relates to a semiconductor device having a cutout structure and a method of manufacturing the same, in particular, to a semiconductor where a SOI (Silicon On Insulator) type semiconductor chip is mounted on a COB (Chip On Board) substrate, and a method of manufacturing the same.

### BACKGROUND OF THE INVENTION

FIG. 8 and FIG. 9 are sectional views showing a part of manufacturing process of the prior-art semiconductor device. As shown in FIG. 8, in a multilayer substrate of the structure where a prepreg 2 is sandwiched between two core base materials 4, 6, inner layer conductive patterns 10 made of Cu are formed. Further, in the core base materials 4 and 6, blind via holes 30 are formed, and the insides thereof are filled up with filling-in resin 32. On the surfaces of the core base materials 4, 6, outer layer conductive patterns 8 made of Cu are formed.

Next, as shown in FIG. 9, a cutout 14 is formed by use of a cutout processing (inner layer cutting) router as disclosed in for example Japanese Unexamined Patent Application Publication No. H8-192309. At this moment, when the bit of the router reaches the surface of the inner layer 10 exactly, cutting is suspended. Thereby, the surface of the inner layer can be exposed uniformly. Thereafter, a semiconductor chip (not illustrated) is packed into the cutout 14.

Another structure of packing a semiconductor chip into the concave portion of a substrate is also disclosed in Japanese Unexamined Patent Application Publication No. H10-214922.

However, when a cutout is formed by use of the router for cutout processing (inner layer cutting), it has been difficult to control to suspend cutting at the moment when the bit of the router reaches the surface of the inner layer, and a highly precise machine was required for it. For this reason, its manufacture cost has inevitably increased.

### OBJECTS OF THE INVENTION

The present invention has been made in consideration of the above circumstances, and accordingly, the object of the present invention is to provide a structure of a semiconductor device that contributes to reduction of the manufacture cost thereof.

Moreover, another object of the present invention is to provide a method of manufacturing a semiconductor device that contributes to reduction of the manufacture cost thereof.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to a first aspect of the present invention, there is provided a semiconductor device that mounts a semiconductor chip in a multilayer substrate, including, inner layer conductive patterns formed in the multilayer substrate; extending conductive portions formed to extend on inner layer conductive patterns in the thickness direction, in the chip mounting area into which the semiconductor chip is mounted; and a cutout portion that is formed by cutting the multilayer substrate, and into which the semiconductor chip is contained, in the chip mounting area. And, in the cutout portion, the underside surface of the semiconductor chip and the inner layer conductive patterns are connected via the extending conductive portions at a same potential.

According to a second aspect of the present invention, there is provided a method of manufacturing a semiconductor device that mounts a semiconductor chip in a cutout formed in a multilayer substrate, including a step of preparing the multilayer substrate having inner layer conductive patterns; a step of forming extending conductive portions made of a conductive material so as to extend in the thickness direction on the inner layer conductive patterns, in the chip mounting area into which the semiconductor chip is mounted; a step of forming a cutout portion into which the semiconductor chip is contained by cutting the multilayer substrate, in the chip mounting area; and a step of mounting the semiconductor chip into the cutout portion. And, when the cutout portion is formed, a part of the extending conductive portions is cut, but the inner layer conductive patterns are not cut. Moreover, the underside surface of the semiconductor chip and the inner layer conductive patterns are connected via the extending conductive portions at a same potential.

Preferably, the extending conductive portions are structured of inner via holes.

Preferably, the inner via holes are formed in a core substrate layer of which upper and lower sides are in contact with prepreg layers. In other words, the core substrate is sandwiched by the prepreg layers.

Preferably, the thickness of the core substrate layer is larger than the thickness of the prepreg layers.

Preferably, a plurality of the inner via holes are formed in the chip mounting area.

Preferably, the extending conductive portions are structured of conductive bumps.

Preferably, the conductive bumps are formed in a prepreg layer of which upper and lower sides are in contact with core substrate layers. In other words, the prepreg layer is sandwiched by the core substrate layers. Herein, in the core substrate layer, blind via holes may be formed.

As the multilayer substrate, a COB substrate may be employed.

As the semiconductor chip, a SOI type chip may be employed.

In the present invention, since cutout processing can be stopped in the middle of the extending conductive portions, there is no need to perform the position control of cutting precisely in comparison with the prior art. That is, the margin in the depth direction at the moment of cutting the cutout portion can be secured. As a result, a relatively low-cost (not so highly precise) machine can be used, and it becomes possible to aim at the reduction of the manufacture cost.

Moreover, there is also an advantage that the freedom degree of bottom wiring of a semiconductor chip is improved, by choosing the position of the extending conductive portions to be arranged on the bottom of the semiconductor chip.

### BRIEF DESCRIPTION OF THE DRAWINGS

FIG. 1 is a cross sectional view showing a part of a manufacturing process of a semiconductor device according to a first preferred embodiment of the present invention.

FIG. 2 is a cross sectional view showing a part of the manufacturing process of a semiconductor device according to a first preferred embodiment of the present invention.

FIG. 3 is a perspective view used for explaining the structure of a semiconductor device according to a first preferred embodiment of the present invention.

FIG. 4 is a cross sectional view showing the structure of a semiconductor device according to a first preferred embodiment of the present invention.

FIG. 5 is a cross sectional view showing a part of the manufacturing process of a semiconductor device according to a second preferred embodiment of the present invention.

FIG. 6 is a cross sectional view showing a part of the manufacturing process of a semiconductor device according to a second preferred embodiment of the present invention.

FIG. 7 is a cross sectional view showing the structure of a semiconductor device according to a second preferred embodiment of the present invention.

FIG. 8 is a cross sectional view showing a part of the manufacturing process of a prior-art semiconductor device.

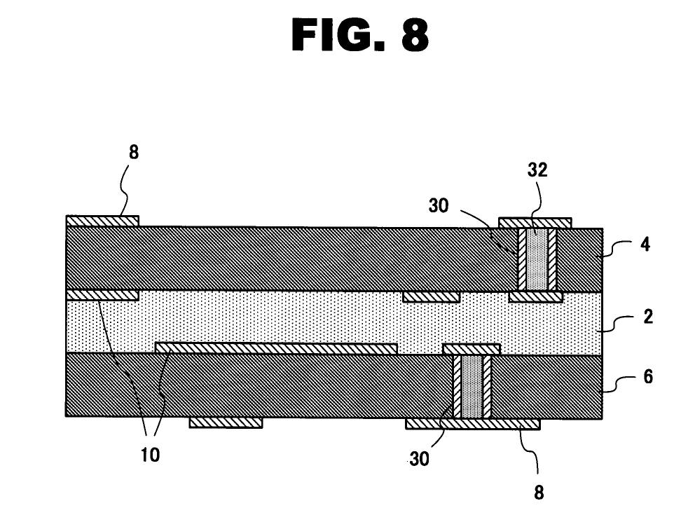

FIG. 9 is a cross sectional view showing a part of the manufacturing process of a prior-art semiconductor device.

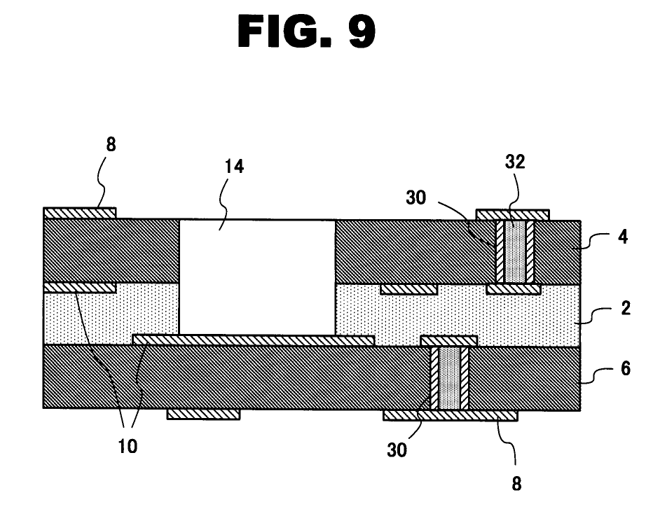

### DESCRIPTION OF CODES

102, 204, 206: Core substrate
104, 106, 202: Prepreg
108, 208: Outer layer pattern
110, 210: Inner layer pattern
112: Inner via hole
114, 214: Cutout
120, 220: Semiconductor chip
212: Conductive bump
230: Blind via hole

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

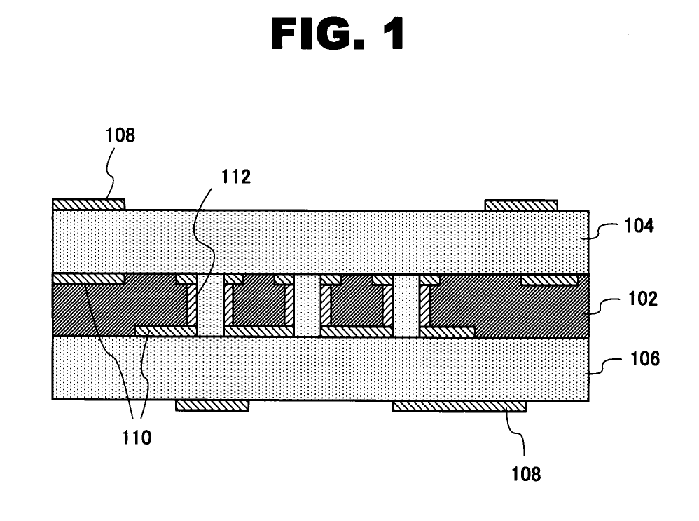

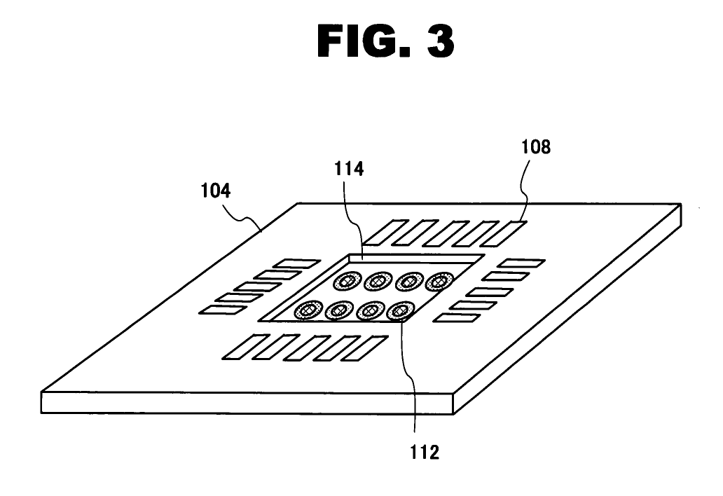

Preferred embodiments according to the present invention are illustrated in more details with reference to the attached drawings hereinafter. FIGS. 1, 2, and 4 are cross sectional views each showing a part of the manufacturing process of a semiconductor device according to a first preferred embodiment of the present invention. FIG. 3 is a perspective view used for explaining the structure of a semiconductor device according to a first preferred embodiment of the present invention.

In a semiconductor device according to the present preferred embodiment, a structure as shown in FIG. 1 is prepared beforehand. Prepregs 104, 106 are formed in both the upper and lower sides of a core substrate (double-sided plate) 102 that have a plurality of inner via holes (extending conductive portions) 112. The thickness of the core substrate 102 is set larger than the thickness of prepregs 104, 106.

Inner layer patterns 110 made of Cu are formed on the upper and lower sides of the core substrate 102. Plural inner via holes 112 in the area where a cutout (114) is prepared and dice-bonded are all connected by the inner layer patterns 110, and have a structure where they are made into a same potential. On the surfaces of the prepregs 104, 106, outer layer conductive patterns 108 made of Cu are formed.

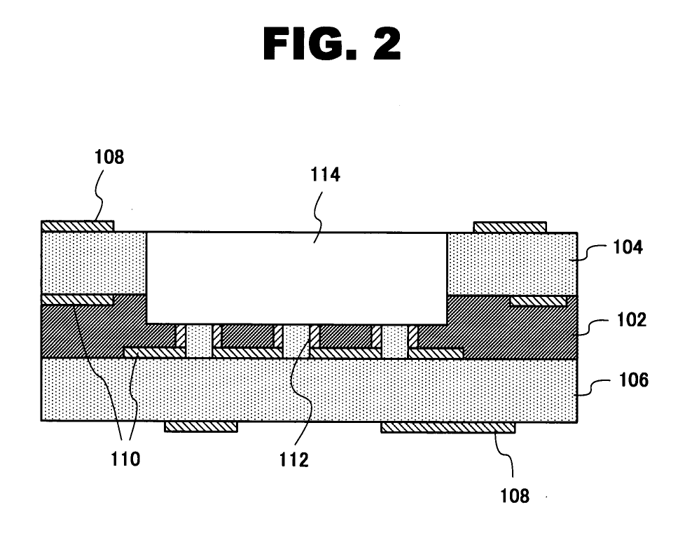

Next, as shown in FIG. 2, by use of a router for cutout processing (inner layer cutting), the cutout 104 is formed in the dice bond area. At this moment, before the bit of the router reaches the middle of the inner via holes 112, and before it reaches the inner layer patterns 110, cutting is suspended. FIG. 3 shows the state of the structure in the stage of FIG. 2 viewed from above.

Herein, since the thickness of the core substrate 102 is larger than the thickness of the prepregs 104, 106, it becomes easy to suspend the cutting in the middle of the core substrate 102, and the processing control of the router becomes easier. Moreover, the plural inner via holes 112 are formed in the dice bond area, and thereby it is possible to make the underside surface of the chip semiconductor chip 120 and the inner layer conductive patterns at a same potential further more reliably.

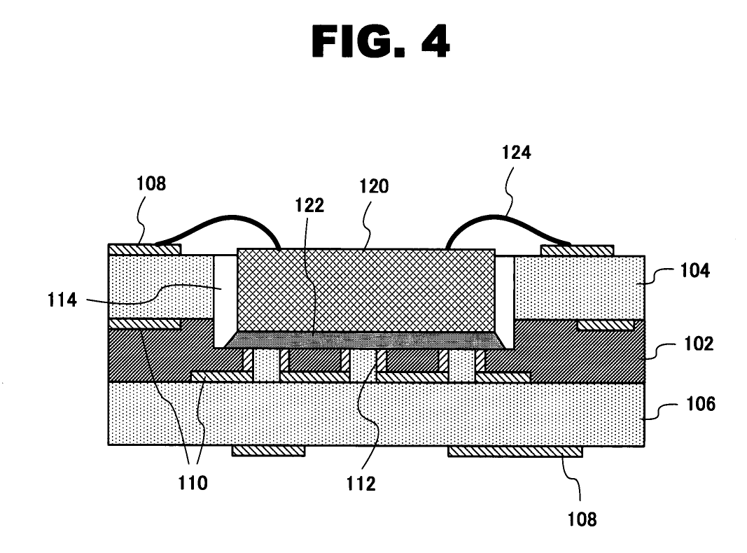

Next, as shown in FIG. 4, a SOI type semiconductor chip 120 is mounted through a conductive dice bond 122 into the cutout 114. Thereafter, the semiconductor chip 120 and the outer layer patterns 108 are connected by a bonding wire 124.

As mentioned above, in the present preferred embodiment, since the cutout processing is stopped in the middle of the inner via holes 112, there is no need to perform the position control of cutting precisely in comparison with the prior art. That is, the margin in the depth direction at the moment of cutting the cutout portion can be secured. As a result, a relatively low-cost (not so highly precise) machine can be used, and it becomes possible to aim at the reduction of the manufacture cost.

Moreover, there is also an advantage that the freedom degree of bottom wiring of the semiconductor chip 120 is improved, by choosing the position of the via holes 112 to be arranged on the bottom of the semiconductor chip 120.

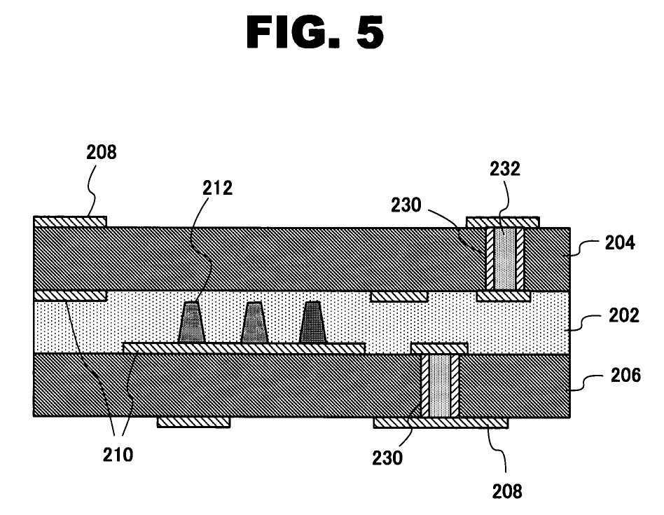

FIG. 5 to FIG. 7 are cross sectional views each showing a part of manufacturing process of a semiconductor device according to a second preferred embodiment of the present invention. In a semiconductor device according to the present preferred embodiment, a structure as shown in FIG. 5 is prepared beforehand. It has a substrate structure where a prepreg 202 is sandwiched between two upper and lower core substrates (double-sided plates) 204, 206. The thickness of the prepreg 202 is set larger than the thickness of the core substrates 204, 206.

Inner layer patterns 210 made of Cu are formed on the upper and lower sides of the prepreg 202. Plural conductive bumps (extending conductive portions) 212 made of silver paste are formed in the area where a cutout (214) is prepared and dice-bonded, and these conductive bumps 212 are all connected by the inner layer patterns 210, and have a structure where they are made into a same potential. On the surfaces of the core substrates 204, 206, outer layer conductive patterns 208 made of Cu are formed. It is preferable that the height of the conductive bumps 212 is formed as high as possible within the range of the thickness of the prepreg 202.

In the prepregs 204, 206, blind via holes 230 are formed, and the insides thereof are filled up with resin 232.

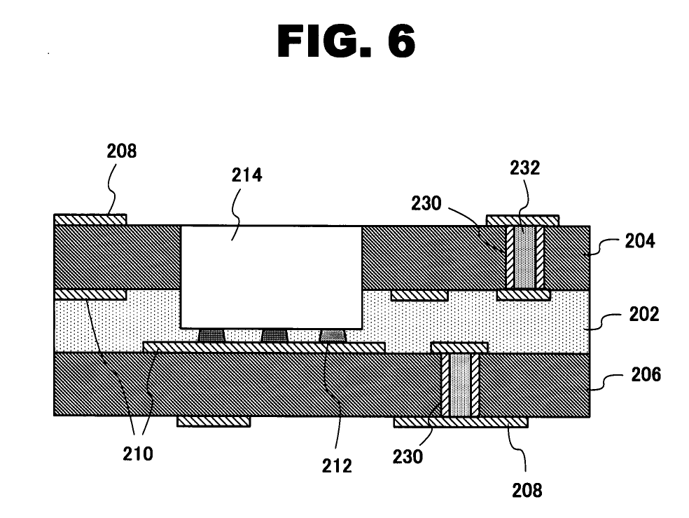

Next, by use of a router for cutout processing (inner layer cutting), as shown in FIG. 6, a cutout 204 is formed in the dice bond area. At this moment, before the bit of the router reaches the middle of the conductive bumps 212, and reaches the inner layer patterns 210, the cutting is suspended.

Herein, since the thickness of the prepreg 202 is larger than the thickness of the core substrates 204,206, it becomes easy to suspend the cutting in the middle of the prepreg 202, and the processing control of the router becomes further easier. Moreover, the plural conductive bumps 212 are formed in the dice bond area, and thereby it is possible to make the underside surface of the chip semiconductor chip (220) and the inner layer conductive patterns at a same potential further more reliably.

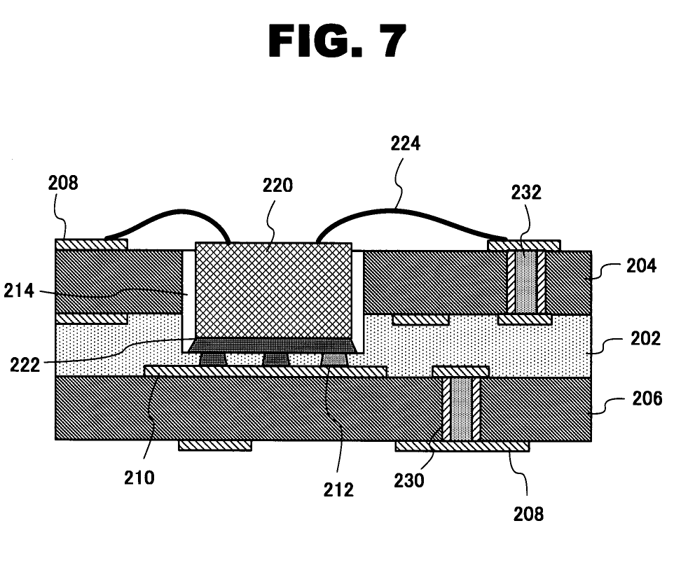

Next, as shown in FIG. 7, a SOI type semiconductor chip 220 is mounted through the conductive dice bond 222 into the cutout 214. Thereafter, the semiconductor chip 220 and the outer layer patterns 208 are connected by a bonding wire 224.

As mentioned above, in the present preferred embodiment, since the cutout processing is stopped in the middle of the conductive bumps 212, there is no need to perform the position control of cutting precisely in comparison with the prior art. That is, the margin in the depth direction at the moment of cutting the cutout portion can be secured. As a result, a relatively low-cost (not so highly precise) machine can be used, and it becomes possible to aim at the reduction of the manufacture cost.

Moreover, there is also an advantage that the freedom degree of bottom wiring of the semiconductor chip 220 is improved, by choosing the position of the conductive bumps 212 to be arranged on the bottom of the semiconductor chip 220.

Furthermore, since the blind via holes 230 can be formed between the first layer and the second layer, and between the third layer and the fourth layer, in comparison with the first preferred embodiment mentioned above, it becomes possible to improve the substrate wiring density.

Heretofore, the present invention has been explained with reference to the preferred embodiments thereof, and as is apparent to those skilled in the art, the present invention is not limited to the above preferred embodiments, but the present invention may be embodied by appropriately modifying the structural components thereof without departing from the spirit or essential characteristics thereof.

In the above preferred embodiments, explanations have been made with the multilayer substrate of four layers as an example, however, the present invention may be applied also to substrates of other numbers of layers. Moreover, although the conductive bumps 212 are used in the second preferred embodiment, it is also possible to use a conductive substance on a line. It is important that it is a conductive substance that extends upward in the thickness direction from the inner layer pattern.

What is claimed is:

1. A semiconductor device that mounts a semiconductor chip in a multilayer substrate, comprising:
an inner layer conductive pattern, formed in the multilayer substrate;
an extending conductive portion, formed to extend on the inner layer conductive pattern in the thickness direction, in a chip mounting area on which the semiconductor chip is mounted; and
a cutout portion that is formed by cutting the multilayer substrate in the chip mounting area, to contain the semiconductor chip is therein, wherein
in the cutout portion, the semiconductor chip and the inner layer conductive pattern are connected via the extending conductive portion at a same potential.

2. A semiconductor device according to claim 1, wherein
the extending conductive portion is structured of an inner via hole.

3. A semiconductor device according to claim 2, wherein
the inner via hole is formed in a core substrate layer, which is sandwiched by prepreg layers.

4. A semiconductor device according to claim 3, wherein
the thickness of the core substrate layer is larger than the thickness of the prepreg layers.

5. A semiconductor device according to claim 2, wherein
a plurality of the inner via holes are formed in the chip mounting area.

6. A semiconductor device according to claim 1, wherein
the extending conductive portion is structured of a conductive bump.

7. A semiconductor device according to claim 6, wherein
the conductive bump is formed in a prepreg layer, which is sandwiched by core substrate layers in the thickness direction.

8. A semiconductor device according to claim 7, wherein
in the core substrate layer, blind via holes are formed.

9. A semiconductor device according to claim 1, wherein
the multilayer substrate is a COB substrate.

10. A semiconductor device according to claim 1, wherein
the semiconductor chip is a SOI type chip.
